(19) United States
(12) Patent Application Publication
(10) Pub. No.: US 2016/0172610 A1
(43) Pub. Date: Jun. 16, 2016

(54) SINGLE-MOLECULE DIODES WITH HIGH ON/OFF RATIOS THROUGH ENVIRONMENTAL CONTROL

(71) Applicant: The Trustees of Columbia University in the City of New York, New York, NY (US)

(72) Inventors: LATHA VENKATARAMAN, New York, NY (US); Luis Campos, Brooklyn, NY (US); Brian Capozzi, Bayside, NY (US)

(21) Appl. No.: 14/937,521

(22) Filed: Nov. 10, 2015

Related U.S. Application Data
(60) Provisional application No. 62/078,804, filed on Nov. 12, 2014.

(51) Int. Cl. H01L 51/05; H01L 51/00; H01L 51/10

(52) U.S. Cl. CPC H01L 51/0595; H01L 51/105; H01L 51/0006; H01L 51/0036; H01L 51/0067; H01L 51/005; H01L 2251/301

(57) ABSTRACT

Techniques for inducing rectification in single-molecule diodes including a symmetric single-molecule adapted to be surrounded by the polar solution. A first electrode can be attached to a first end of the symmetric single-molecule and have a first area adapted for exposure to the polar solution. A second electrode can be attached to a second end of the symmetric single-molecule opposite the first end and have a second area adapted for exposure to the polar solution. The first and second electrodes and the single-molecule can a single-molecule junction, and the first area and second areas of the diodes can differ in size to create an environmental asymmetry. A voltage source can be coupled to the first and second electrodes configured to selectively control the environmental asymmetry and thereby induce current rectification.

### CROSS-REFERENCE TO RELATED APPLICATION

This application is related to U.S. Provisional Application Ser. No. 62/078,804, filed on Nov. 12, 2014, which is incorporated herein by reference in its entirety and from which priority is claimed.

### STATEMENT REGARDING FEDERALLY SPONSORED RESEARCH

This invention was made with government support under Grant Nos. DMR-1206202 and DMR-1122594 awarded by the National Science Foundation. The government has certain rights in the invention.

### BACKGROUND

Molecular electronics can be used to implement miniature electronic devices, e.g., by way of bottom-up fabrication utilizing sub-nanometer scale components. Single-molecule diodes, which function as an electronic component that directs current flow, have been developed. Certain diodes have relied on asymmetric molecular backbones, asymmetric molecular electrode linkers, or asymmetric electrode materials.

However, such molecular diodes have had limited potential for functional applications due to low conductances, low rectification ratios (“on”/“off” current<10), sensitivity to junction structure, and high operating voltages.

### SUMMARY

The presently disclosed subject matter provides single-molecule diodes with high on/off ratios. The disclosed subject matter also provides methods to induce rectification in conventionally symmetric single-molecule junctions.

In one aspect of the disclosed subject matter, a single-molecule diode can include a single-molecule surrounded by a polar environment. The diode can include a first electrode, attached to a first end of the single-molecule, with a first area exposed to the polar environment, and a second electrode, attached to an opposite end of the single-molecule, with a second area exposed to the polar environment. The first and second electrodes and the single-molecule can form a single-molecule junction, and the first area of the first electrode exposed to the polar environment can be larger than the second area of the second electrode exposed to the polar environment, thereby creating an environmental asymmetry. A voltage source coupled to the first and second electrodes can be configured to selectively control the environmental asymmetry and thereby induce current rectification.

In accordance with certain exemplary embodiments, the single-molecule can be a symmetric single-molecule. the single-molecule can include three thiophene-1,1-diooxide units (TDO3), four thiophene-1,1-diooxide units (TDO4), or five thiophene-1,1-diooxide units (TDO5) flanked by two gold-binding methyl-sulfide bearing thiophenes. Alternatively, the single-molecule can be 4,4′-bipyridine or 4,4″-diamino-p-terphenyl. In certain embodiments, the polar solution can be a polar solution. The polar environment can include propylene carbonate, water, an electrolytic solution, or an ionic liquid.

In accordance with certain exemplary embodiments, the first and second electrodes can be formed from the same material. The first and second electrodes can be formed from a metal, such as gold. The first area of the first electrode can be approximately 1 mm² and the second area of the second electrode can be approximately 1 μm². The second electrode can be an atomically sharp scanning tunneling microscope tip, insulated by a wax to expose a smaller second area of the second electrode.

In accordance with another aspect of the disclosed subject matter, a method for inducing rectification in a single-molecule junction can include surrounding a single-molecule by a polar environment. The method can include attaching a first electrode attached to a first end of a single-molecule and attaching a second electrode attached to a second end of the single-molecule opposite the first end. An environmental asymmetry can be created by exposing a first area of the first electrode to a polar environment and exposing a second area of the second area of the polar environment, where the first area of the first electrode is larger than the second area of the second electrode. Rectification can be induced by selectively controlling the environmental asymmetry.

### BRIEF DESCRIPTION OF THE DRAWINGS

Further features, the nature, and various advantages of the disclosed subject matter will be more apparent from the following detailed description and the accompanying drawings in which:

FIG. 1A illustrates a symmetric single-molecule junction using asymmetric area electrodes in accordance with an embodiment of the disclosed subject matter.

FIG. 1B depicts a conductance histogram for a single-molecule junction using asymmetric area electrodes in a polar solution in accordance with an embodiment of the disclosed subject matter.

FIG. 1C depicts a two-dimensional absolute current versus voltage histogram for a single-molecule junction using asymmetric area electrodes in a polar solution in accordance with an embodiment of the disclosed subject matter.

FIG. 1D depicts a two-dimensional absolute current versus voltage histogram for a single-molecule junction in a non-polar, non-ionic solvent.

FIG. 2A depicts a graph of the average IVs for three symmetric single-molecule junctions using asymmetric area electrodes in a polar solution in accordance with embodiments of the disclosed subject matter.

FIG. 2B depicts a graph of the average IVs for three symmetric single-molecule junctions using asymmetric area electrodes in a non-polar, non-ionic solvent in accordance with embodiments of the disclosed subject matter.

FIG. 3A depicts a graph of experimental determination of orbital coupling strength for three single-molecule junctions using asymmetric area electrodes in polar and non-polar solutions in accordance with an embodiment of the disclosed subject matter.

FIG. 3B depicts a graph of experimental determination of orbital level alignment for three single-molecule junctions using asymmetric area electrodes in polar and non-polar solutions in accordance with an embodiment of the disclosed subject matter.

FIG. 3C is a schematic diagram of the single-molecule junction structures used to compute the transmission characteristics.

FIG. 3D is a plot of calculated transmission function for a single-molecule junction with no solvent molecules and with solvent molecules.

FIG. 4 depicts a conductance histogram for a symmetric single-molecule junction in a in a non-polar, non-ionic solvent.

FIG. 5 depicts high- and low-G conductance values as a function of applied voltage for a symmetric single-molecule junction in a variety of polar solutions.

FIG. 6 depicts conductance histograms for a symmetric single-molecule junction in a polar solvent and a non-polar solvent.

FIG. 7 depicts a conductance histogram for three symmetric single-molecule junctions in a non-polar solvent.

FIG. 8 depicts two-dimensional IV histograms for three symmetric single-molecule junctions in polar and non-polar solvents.

FIG. 9 depicts a single Lorentzian transmission function and rectification ratio of applied voltage.

FIG. 10 depicts sample IV measurement in accordance with the disclosed subject matter.

FIG. 11 depicts junction transmission functions for a symmetric single-molecule junction calculated without solvent, with solvent on one electrode, and with solvent on both electrodes.

FIG. 12 illustrates the synthesis of symmetric single-molecule junctions in accordance with the disclosed subject matter.

FIG. 13 depicts UV-vis spectrum and cyclic voltammogram of a symmetric single-molecule junction in accordance with the disclosed subject matter.

FIGS. 14A and 14B depict the NMR spectra for a symmetric single-molecule junction in accordance with the disclosed subject matter.

Throughout the drawings, the same reference numerals and characters, unless otherwise stated, are used to denote like features, elements, components or portions of the illustrated embodiments. Moreover, while the disclosed subject matter will now be described in detail with reference to the figures, it is done so in connection with the illustrative embodiments.

### DETAILED DESCRIPTION

The disclosed subject matter provides conventionally-symmetric single-molecule diodes with high on/off ratios and techniques to induce rectification in conventionally symmetric single-molecule junctions.

Generally, for purpose of illustration, single-molecules attached to electrodes (single-molecule junctions) can be made to act as a variety of circuit elements, including resistors, switches, transistors, and, indeed, diodes. Moreover, quantum mechanical effects, such as interference, can become manifest in the conductance properties of molecular junctions. Since a diode acts as an electricity valve, its structure should be asymmetric so that electricity flowing in one direction experiences a different environment than electricity flowing in the other direction. In order to develop a single-molecule diode, certain techniques have simply designed molecules that have asymmetric structures. However, although asymmetric molecules can display diode-like properties, they can suffer from lower current flow in both “on” and “off” directions, and the ratio of current flow in these directions can be low.

In accordance with the disclosed subject matter, single-molecule diodes can be formed from single-molecules including symmetric molecules. An environmental asymmetry can be created by surrounding the molecule with an ionic solution and using electrodes of different sizes to contact the molecule. In this manner, rectification ratios can be increased relative to conventional designs even at low operating voltages. Using symmetric molecules can also facilitate the creation of molecular diodes by self-assembly since the orientation of the molecule is no longer an issue.

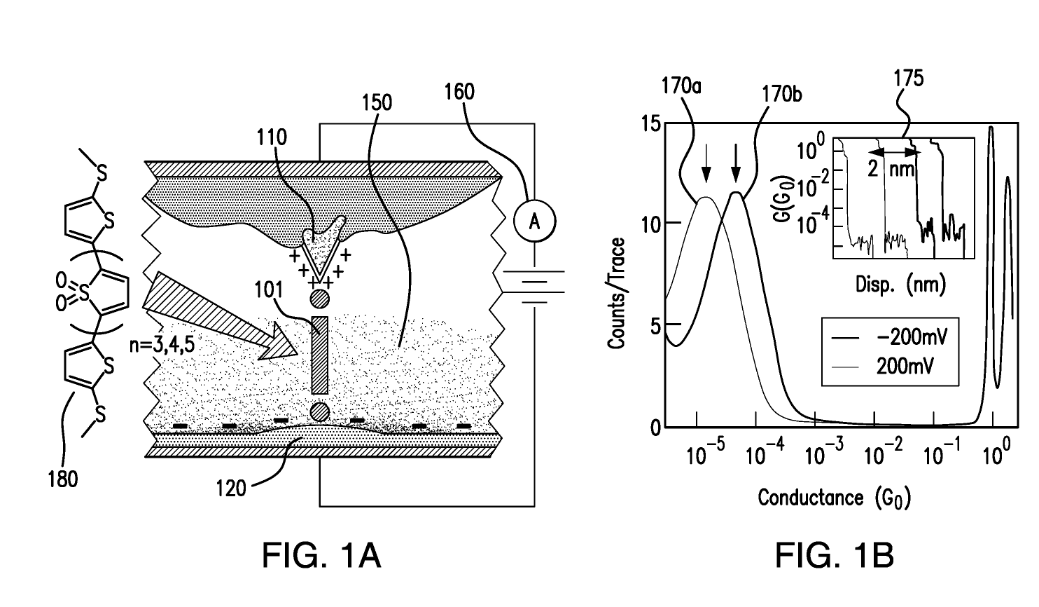

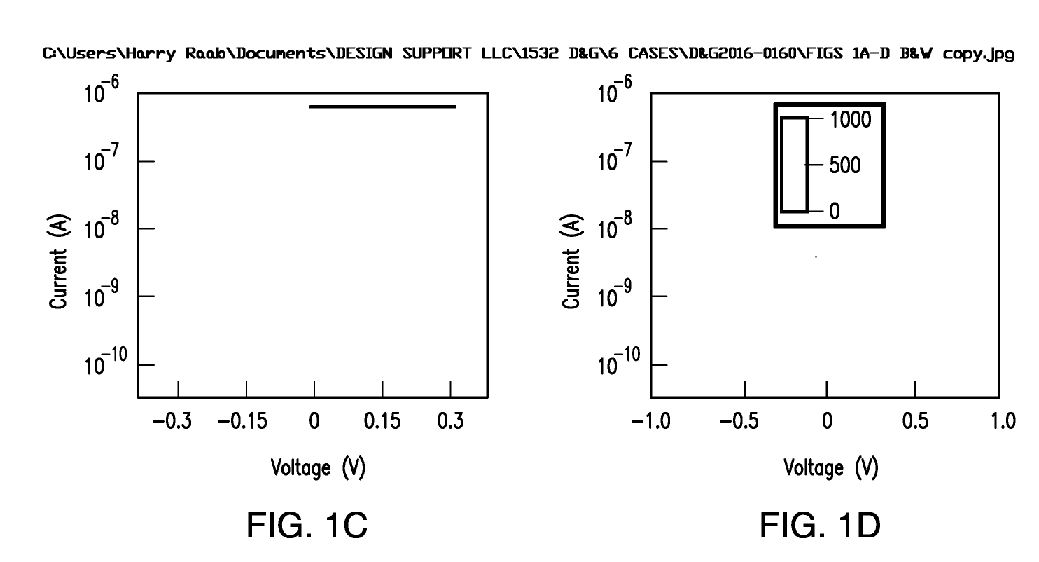

In accordance with the disclosed subject matter, and with reference to FIG. 1, a single-molecule diode can include a symmetric single-molecule 101 surrounded by a polar or ionic environment 150. A diode can be created by attaching electrodes (110, 120) of differing sizes to the molecule 101. For example, in connection with an exemplary embodiment, a first electrode 110 can be attached to a first end of the symmetric single-molecule 101 and a second electrode 120 can be attached to the other end of the symmetric single-molecule 101. The first 110 and second 120 electrodes and the single-molecule 101 thereby form a single-molecule junction. The area of the first electrode 110 exposed to the environment 150 can be different than the area of the second electrode 120 exposed to the solvent. In this manner, an environmental asymmetry can be created. A voltage source 160 electrically coupled to the first 110 and second 120 electrodes can be configured to selectively control the environmental asymmetry and thereby induce current rectification. For example, the voltage source 160 can be configured to positively and negatively charge the first 110 and second 120 electrodes, such that current will flow through the single-molecule 101 and reverse polarity to so that the current will flow in the opposite direction. The differing surface areas of the first 110 and second 120 electrodes can create an environmental asymmetry such that the magnitude of the current while flowing in one direction is different than the magnitude of the current while flowing in the opposite direction at the same voltage magnitude but opposite polarity.

As disclosed herein, the single-molecule 101 can include any symmetric single-molecule. In accordance with certain exemplary embodiments, for the purpose of illustration and not limitation, the single-molecule 101 can be an oligomer consisting of three to five thiophene-1,1-dioxide units flanked by two gold-binding methyl-sulfide bearing thiophenes. That is, for example, the single molecule can include three thiophene-1,1-diooxide units (TDO3), four thiophene-1,1-diooxide units (TDO4), or five thiophene-1,1-diooxide units (TDO5) flanked by two gold-binding methyl-sulfide bearing thiophenes. FIG. 1A includes a depiction of the TDOn molecular structure 180 with alkyl side chains omitted for clarity.

One of skill in the art will appreciate, however, that the disclosed subject matter is not limited to any particular molecule. For example, the single-molecule 101 can be 4,4′-bipyridine, 4,4″-diamino-p-terphenyl, or any other symmetric single-molecule. As explained in connection with the Example below, for purpose of illustration and not limitation, an exemplary embodiment of the disclosed subject matter can include a single-molecule 101 comprising TDO5. As explained herein, TDO5 flanked by two gold-binding methyl-sulfide bearing thiophenes can allow for an average rectification ratio in excess of 200, and individual rectification ratios approaching 500, at operating voltages as low as +/−370 mV.

As disclosed herein, the polar environment 150 can include any polar environment, including a polar solution, polar gel, or a solid electrolyte. In accordance with an exemplary embodiment, the polar environment 150 can be a polar solution. For example, and not limitation, the polar environment can include propylene carbonate (PC), water, an electrolytic solution, or an ionic liquid. FIG. 1C illustrates a two-dimensional absolute current versus voltage histogram for an exemplary symmetric single-molecule diode in an exemplary solvent in accordance with the disclosed subject matter. In particular, FIG. 1C depicts a two-dimensional absolute current versus voltage histogram for TDO5 in PC in accordance with the disclosed subject matter, with examples of junctions with high rectification depicted in the inset. As illustrated by FIG. 1C, the there is a higher current at negative voltages as compared to positive ones, yielding an asymmetry characteristic of diodes. By contrast, FIG. 1D illustrates a two-dimensional absolute current versus voltage histogram for TDO5 in a non-polar, non-ionic solvent, 1,2,4-trichlorobenzne (TCB), and does not display an asymmetry. That is, FIG. 1D illustrates that, in a non-polar, non-ionic medium, the measured current at a given magnitude of applied voltage is the same regardless of the polarity.

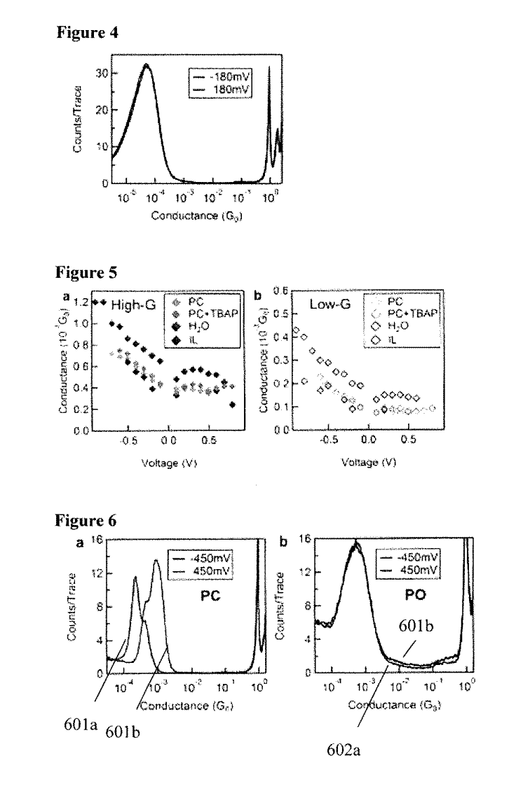

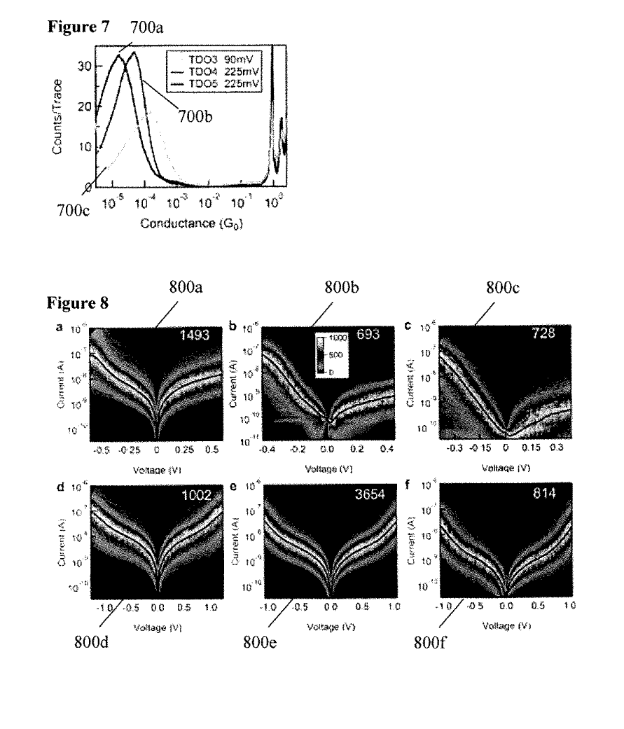

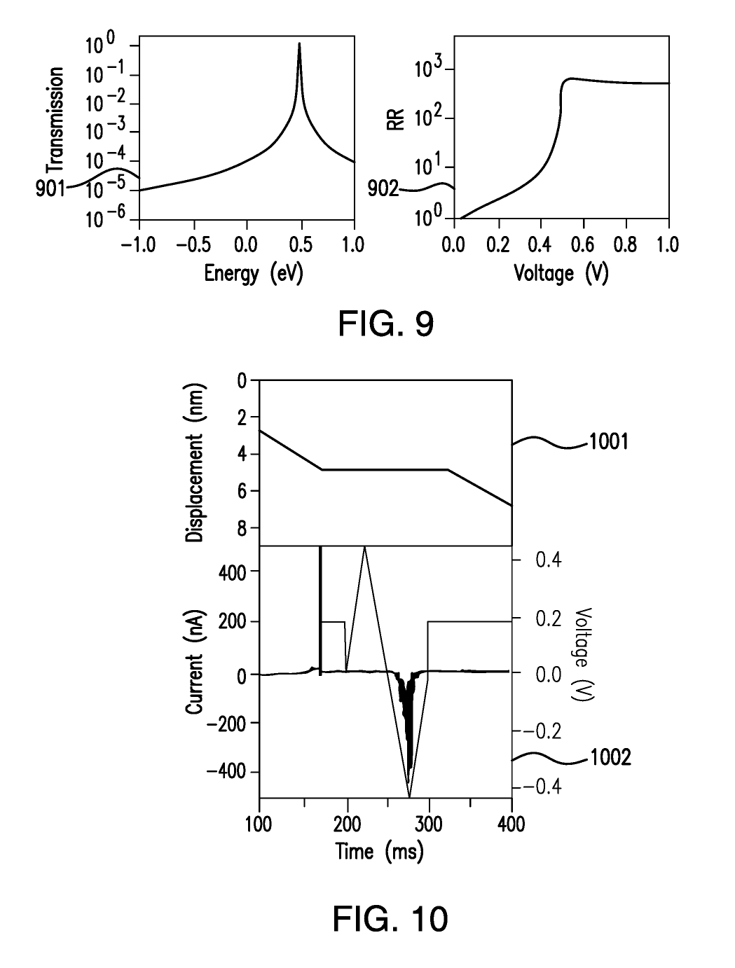

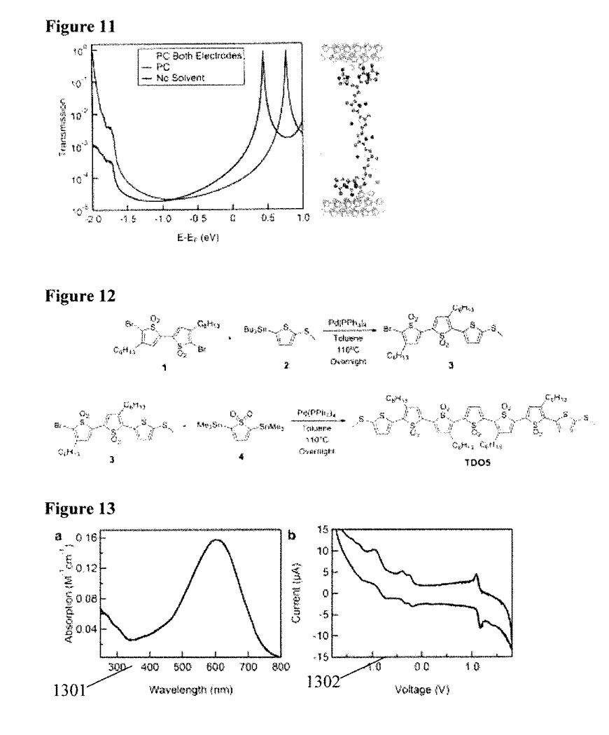

FIG. 1B depicts conductance histograms for TDO4 in PC taken at −180 mV (170b) and +180 mV (170a) in accordance with the disclosed subject matter. As illustrated by FIG. 1B, there is a divergence in single-molecule junction conductance when measurements are performed at negative and positive voltages. By contrast, FIG. 4 depicts conductance histograms for TDO4 in TCB. As illustrated by FIG. 4, and in contrast to FIG. 1B, there is no change in conductance at the two different polarities.

FIG. 5 illustrates high-G and low-G conductance values as a function of applied voltage for 4,4′-bipyridine measured in a variety of polar solvents, including PC, PC with tetrabutylammonium perchlorate (TBAP), water, and an ionic liquid N,N-diethyl-N-(2-methoxyethyl)-N-methylammonium bis(trifluoromethylsulphonyl-imide (DEME-TFSI (IL)), in accordance with the disclosed subject matter. As illustrated by FIG. 5, the symmetric single-molecule diode displays an asymmetry with each of the solvents. Additionally, for purpose of illustration and not limitation, FIG. 5 demonstrates that the low-G conductance feature can be more sensitive to applied voltage; this can occur because the molecular resonance is closer to E_{F}, which is in agreement with theoretical understanding as explained in more detail below.

FIG. 6 depicts conductance histograms for a single-molecule 101 comprising 4,4″-diamino-p-terphenyl in PC and in phenyl octane (PO), which is non-polar, each at +/−450 mV. As illustrated by FIG. 6, there is a divergence in junction conductance between measurements taken at negative voltages in PC (601b) and measurements taken as positive voltages in PC (601a), but no divergence between measurements taken at positive and negative voltages in PO (602a and 602b).

FIG. 8 depicts two-dimensional IV histograms for TDO3, TDO4, and TDO5, each in PC and TCB. TDO3 in PC is depicted in histogram 800a. TDO4 in PC is depicted in histogram 800b. TDO5 in PC is depicted in histogram 800c. TDO3 in TCB is depicted in histogram 800d. TDO4 in TCB is depicted in histogram 800e. TDO5 in TCB is depicted in histogram 800f. As depicted by the histograms in FIG. 8, asymmetries occur between positive and negative voltages for TDO3, TDO4, and TDO5 in PC (a polar solvent), but not for TDO3, TDO4, and TDO5 in TCB (a non-polar, non-ionic solvent).

In accordance with certain exemplary embodiments, the first 110 and second 120 electrodes can be formed from the same material. The electrodes (110, 120) can be formed from a metal, such as gold. As embodied herein, the surface area of the first electrode 110 exposed to the solution 150 can be different than the surface area of the second electrode 120 exposed to the solution 150. In this manner, an environmental asymmetry can be created, and thus rectification can be induced by exploiting this environmental asymmetry. The difference in the surface area between the electrodes (110, 120) can be varied as desired based on the desired operating parameters of the diode. Generally, for purpose of illustration and not limitation, the surface areas of the first and second electrodes (110, 120) can differ by an order of magnitude or several orders or magnitude. For example, the area of the first electrode 110 can be approximately 1 mm² and the area of the second electrode 120 can be approximately 1 μm². In certain exemplary embodiments, one of the electrodes can be formed in the shape of a tip, such as the same of a scanning tunneling microscope tip, and insulated by a wax to expose only the second area of the second electrode.

As disclosed herein, rectification ratios attainable by embodiments disclosed herein can be in excess of 200 at operating voltages as low as 370 mV for hundreds of junctions based on a symmetric small-gap thiophene-1,1-dioxide oligomer. Accordingly, the disclosed subject matter can provide for functional molecular-scale devices. Moreover, the disclosed method does not require difficult chemical modifications that have been employed to control molecule directionality in a junction. Additionally, the disclosed subject matter can provide for junctions utilizing any electrode material, including carbon nanotubes or graphene, by controlling the relative areas of electrodes exposed to solvents.

### EXAMPLES

The scanning tunneling microscope-based break junction technique (STM-BJ) can be used in order to rapidly and reproducibly measure the conductance and current-voltage characteristics of thousands of single-molecule junctions. To achieve high rectification with this technique, the interfacial interactions between the electrodes (110, 120) and the medium can be controlled by performing measurements in propylene carbonate (PC), a polar solvent 150, using an STM tip (110) insulated with a wax to reduce its area to ca. 1 μm², while using a gold substrate (120) that has an area greater than 1 mm² as illustrated in FIG. 1A. The insulation on the tip can serve to reduce any background capacitive and faradaic electrochemical currents from the ions in the solvent and allow for control of the electrostatic environment around the tip 110 and substrate 120.

First, single-molecule junction rectification in an oligomer consisting of four thiophene-1,1-dioxide units flanked by two gold-binding methyl-sulfide bearing thiophenes (TDO4) is demonstrated, as shown in FIG. 1A. Sample conductance versus displacement traces for TDO4 measured in PC are shown in the inset 175 of FIG. 1B. Under the conditions described above, there is a significant difference in single-molecule junction conductance when measurements are performed at +180 mV or −180 mV (tip relative to substrate). When thousands of these conductance traces are compiled, without data selection, into one-dimensional linearly binned conductance histograms (FIG. 1B), the conductance measured at −180 mV is greater than the conductance measured at +180 mV by a factor of 3.25; this is a large difference for such a low-bias measurement. Furthermore, this dependence of conductance on the polarity of the applied voltage is not encountered when TDO4 is measured in a non-polar and non-ionic solvent, such as 1,2,4-trichlorobenzne, as illustrated in FIG. 4.

The disclosed method of creating a molecular rectifier is not unique to TDO4 in PC; a single-molecule diode can be created out of any molecule in any polar solvent. This can be demonstrated by showing rectification in molecular junctions with 4,4′-bipyridine and 4,4″-diamino-p-terphenyl in PC and with 4,4′-bipyridine in other polar media including water, electrolytic solutions and ionic liquids, as illustrated by FIGS. 5 and 6.

Next, high rectification ratios in single-molecule junctions are demonstrated by performing current-voltage (IV) measurements on TDO5, as illustrated in FIG. 1A, in PC. In connection with this demonstration, thousands of individual IVs are obtained, and only traces containing a molecular feature that sustains the entire voltage ramp are considered. For example, approximately 1000 traces per molecule can be obtained. These traces can then be overlaid and compiled into a two-dimensional current versus voltage histogram, as illustrated in FIG. 1C. As illustrated by the FIG. 1C, the plot is asymmetric, showing a much higher current at negative voltages as compared to positive ones. Results from analogous IV measurements in 1,2,4-trichlorobenzene (TCB) are shown in FIG. 1D, where no asymmetry is observed. In order to obtain a quantitative value for the rectification ratio (Iₒₙ/I_{off}), each vertical slice of the 2D histogram can be fit with a Gaussian, and a most probable current value can be determined at each voltage to obtain an average IV curve, as illustrated by the overlays of FIG. 1C and FIG. 1D. In connection with this example, a rectification ratio for TDO5 was found to be greater than 200 at +/−370 mV in PC. While this “average” rectification ratio is already the highest reported for single-molecule junctions, several single-trace plots of these junctions display exceptionally high rectifying behavior, with rectification ratios over 500 as shown in the inset of FIG. 1C.

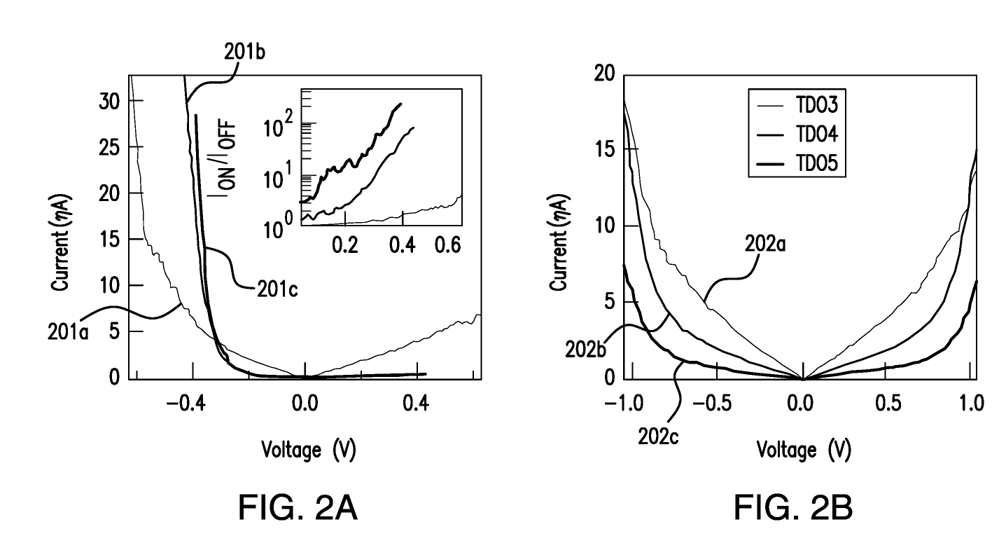

FIG. 2 illustrates the rectification mechanism in accordance with the disclosed subject matter by comparing IV measurements from a family of oligothiophene derivatives containing 3-5 thiophene-1,1-dioxide units (TDO3-TDO5). FIG. 2A includes a plot of average IV for TDO3 in PC 301a, TDO4 in PC 301b, TDO5 in PC 301c, and FIG. 2B includes a plot of average IV for TDO3 in TCB 302a, TDO4 in TCB 302b, and TDO5 in TCB 302c. For junctions in this series, the gap between resonances associated with the highest occupied and the lowest unoccupied molecular orbitals (HOMO-LUMO) can decrease with increasing molecular length, with the LUMO resonance getting closer to the Fermi Energy (E_{F}). As illustrated by FIG. 2A, the three IV curves for TDO3-TDO5 display strong asymmetries, with significantly more current on the “on” side (negative tip bias relative to the substrate) as compared to the “off” side. For all molecules, the lower current portion of the IV can exhibit a more linear dependence of current on voltage, while the high current portions display highly non-linear behavior. Additionally, as illustrated by FIG. 2, the “on” current can reach approximately 0.25 μA and can occur at lower bias with increasing molecular length.

The rectification ratio for each molecule as a function of the magnitude of the applied voltage is shown in the inset of FIG. 2A. In connection with this example, rectification ratios of ˜4 at 0.6V for TDO3, ˜90 at 0.42V for TDO4, and ˜200 at 0.37V for TDO5 were found. Moreover, in connection with this example, rectification occurs at a low operating voltage. The analogous IV measurements carried out in TCB are shown in FIG. 2B, where symmetric IV curves that become increasingly non-linear at higher applied voltages are observed. Evaluating these data, the increase in rectification ratio and the increasingly non-linear IV behavior stems from molecular resonances being close to E_{F}, a consequence of the decreasing HOMO-LUMO gap with length.

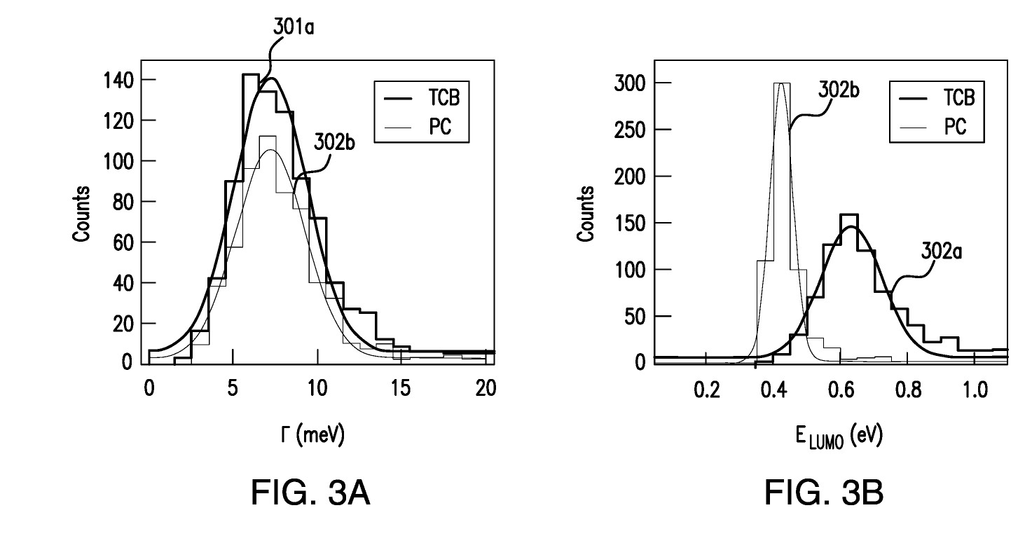

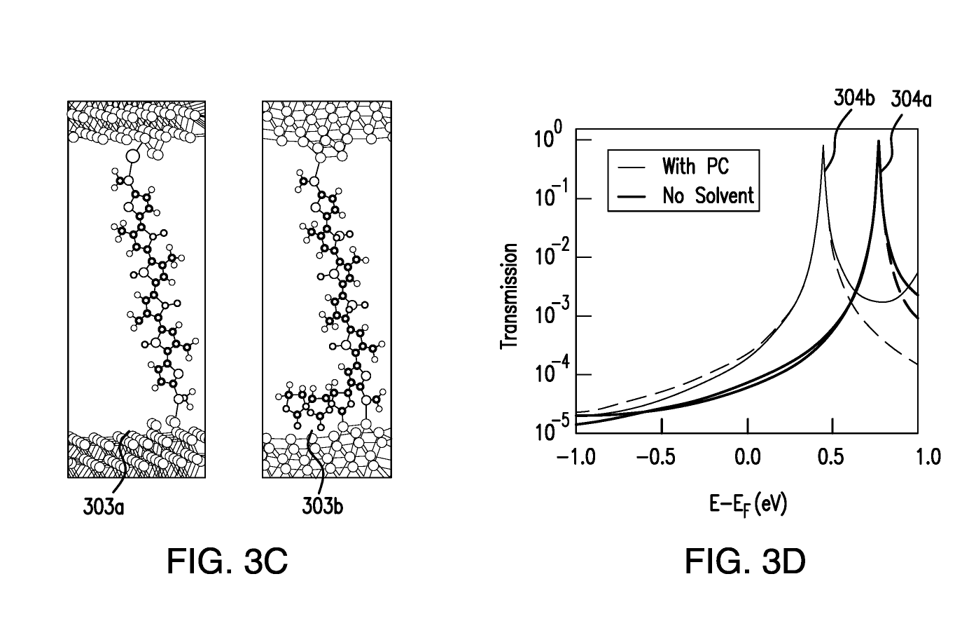

For purpose of illustration and not limitation, and with reference to FIG. 12, an exemplary method for synthesizing TDO5 in accordance with the disclosed subject matter will now be described. However, one of skill in the art will appreciate that a variety of other suitable methods for synthesizing TDO5 can be employed as desired. In this example, with reference to FIG. 3, Compound 1 (1.67 g 3 mmol) and compound 2 (1.26 g, 3 mmol) can be dissolved in 30 mL toluene, under nitrogen. Pd(PPh₃)₄ (173 mg, 0.15 mmol) can be added and the resulting mixture can be stirred at 80° C. for 2 h. After cooling to room temperature, the reaction mixture can be extracted with CH₂Cl₂, washed twice with water, and then dried with Na₂SO₄. After removing the solvent, the crude product can be purified by column chromatography on silica gel, and eluted with 25% EtOAc/hexanes to yield compound 3 as red solid (0.82 g, yield: 46%). 2,5-bis(trimethylstannyl)thiophene (1.74 g, 4.25 mmol) can be dissolved in 60 mL CH₂Cl₂, and the mixture can be cooled to 0° C. 2.2 equivalents of Rozen's reagent (HOF.CH₃CN, 60 mL, 0.14 M) can then be added to the reaction flask. The reaction can be stopped after 30 min and the excess HOF.CH₃CN can be quenched with saturated sodium bicarbonate. The mixture can be poured into water and extracted with CH₂Cl₂; the organic can be layer dried over sodium sulfate. After removing the solvent, the crude product can be purified by recrystallization in ethanol to give compound 4 as a white solid 0.48 g, yield: 26%. ¹H NMR (400 MHz, CDCl₃, ppm): δ 0.43 (s, 18 H), 6.69 (s, 2H). Compound 4 (26 mg, 0.058 mmol), compound 3 (70 mg, 0.116 mmol), and Pd(PPh₃)₄ (4 mg, 0.003 mmol) can be charged in a 20-mL reaction vial, the reaction vial can be purged with nitrogen and securely sealed. The reaction mixture can be stirred at 110° C. for 18 h before it is cooled to room temperature. After removal of the solvent, the dark crude product can be purified by chromatography on silica gel using 60% dichloromethane in hexanes as eluent, and the titled compound can be obtained as a dark solid (53 mg, 78%). ¹NMR (400 MHz, CDCl₃, ppm): δ 0.88-0.93 (m, 12H), 1.33-1.36 (m, 16H), 1.46 (m, 8H), 1.63-1.70 (m, 8H), 2.61 (s, 6H), 2.69 (t, J=8 Hz, 4H), 2.94 (t, J=8 Hz, 4H), 7.07 (d, J=4 Hz, 2H), 7.20 (s, 2H), 7.27 (s, 2H), 7.47 (s, 2H), 7.62 (d, J=4 Hz, 2H). ¹³C NMR (100 MHz, CDCl₃, ppm): δ 13.97, 20.45, 22.45, 22.47, 27.30, 28.82, 29.23, 29.69, 30.36, 31.36, 31.42, 31.98, 125.90, 126.51, 127.26, 127.46, 12S.77, 129.09, 130.62, 130.93, 131.56, 133.36, 133.88, 144.87, 145.51. HRMS (FAB) m/z calcd for C₅₄H₆₈O₁₀S₉: 1165.70. Found (M+Na)⁺: 1 186.68.

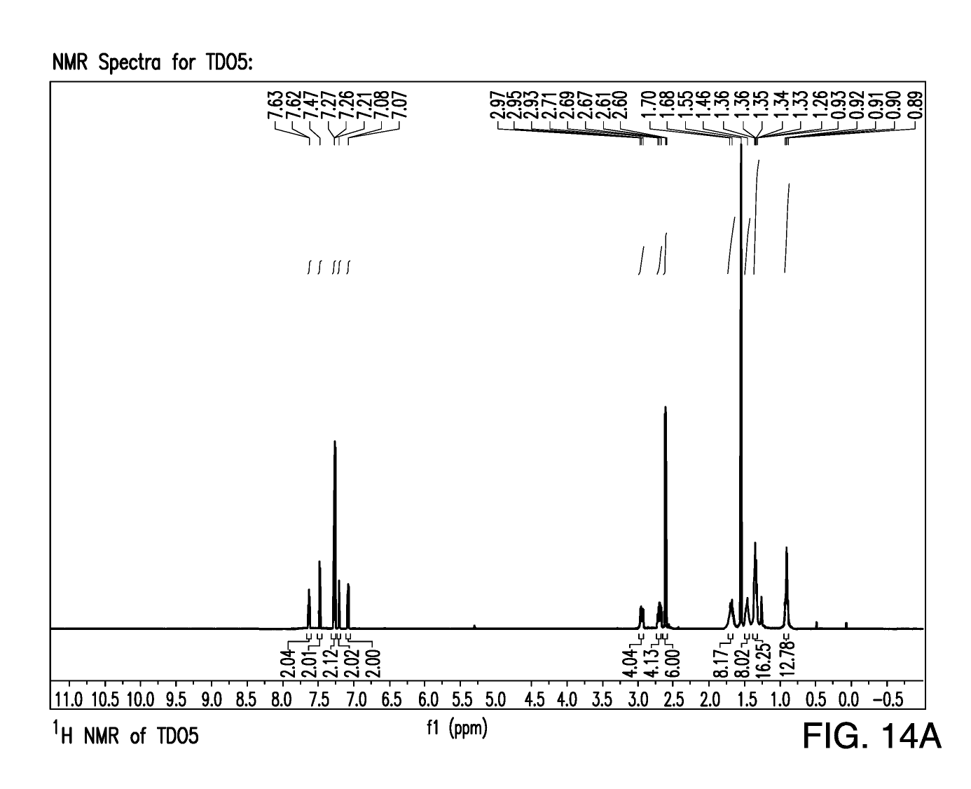

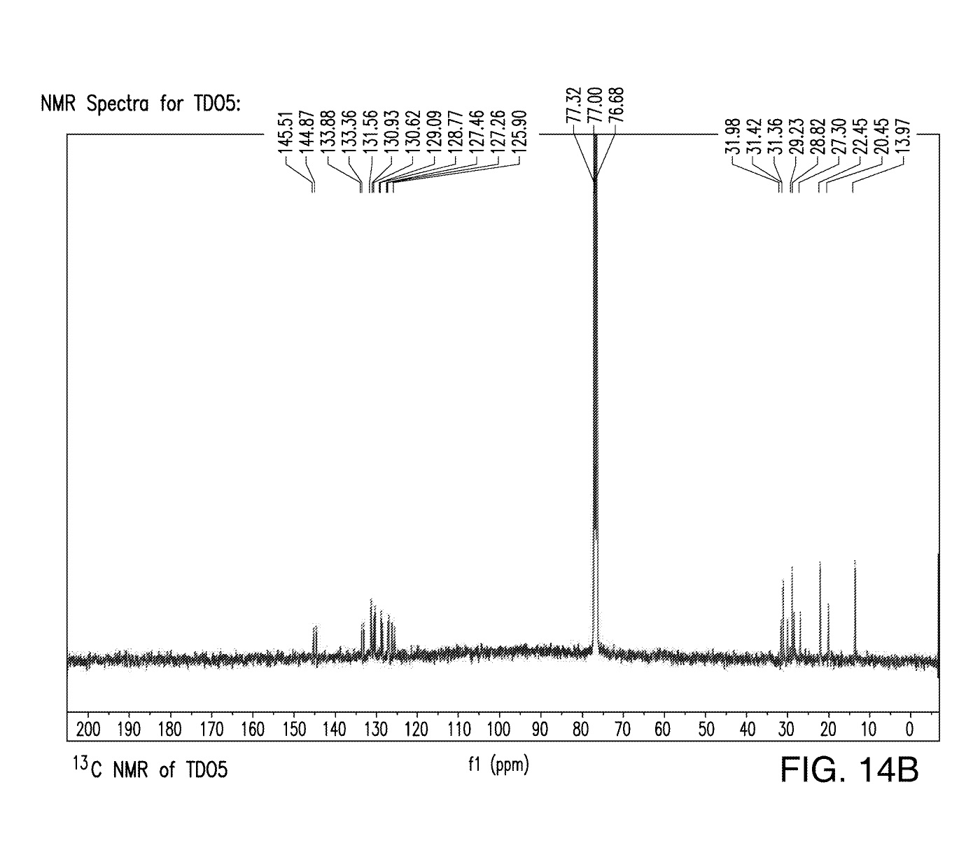

FIG. 13 depicts a UV-vis spectrum 1301 and cyclic voltammogram 1302 of TDO5 as synthesized above. UV-vis measurements can be performed using a 10 μM solution of TDO5 in dichloromethane, resulting in a plot 1301 substantially similar to that in FIG. 13. Cyclic voltammetry measurements can be performed using a 10 mM solution of TDO5 with 100 mM tetrabutylammonium hexafluorophosphate as supporting electrolyte in dichloromethane, resulting in a plot 1302 substantially similar to that in FIG. 13. Measurement can be made using a standard three-electrode set up, with Pt disk, Pt wire, and Ag/AgCl electrodes serving as the working electrode, counter electrode, and reference electrode, respectively. For calibration, the redox potential of ferrocene/ferrocenium (Fe/Fe⁺) can be measured under the same conditions, and is located at 0.31V relative to the Ag/AgCl electrode. FIG. 14 depicts the NMR spectra for TDO5 synthesized as described above. FIG. 14 depicts both the ¹H NMR and ¹³C NMR of TDO5.

For purpose of illustration and not limitation, an exemplary method for taking conductance measurements, such as those referenced in this example, will be described. However, one of skill in the art will appreciate that a variety of other suitable techniques can be employed as desired. Conductance measurements can be carried out using the scanning tunneling microscope-based break junction (STM-BJ) technique. Conductance measurements for the TDOn family can be carried out in dilute solutions (10 μM-100 μM) in propylene carbonate and 1,2,4-trichlorobenzene. The insulated tips can be created by driving a mechanically cut gold tip through molten wax. One dimensional conductance histograms can be constructed using logarithmic bins (100 per decade) without any data selection.

For purpose of illustration and not limitation, an exemplary method for taking IV measurements, such as those referenced in this example, will be described. However, one of skill in the art will appreciate that a variety of other suitable techniques can be employed as desired. IV measurements can be performed using STM-BJ, with a slightly modified procedure. Instead of continuously retracting the tip from the substrate, the tip can be withdrawn for 150 ms, held for 150 ms and then withdrawn for an additional 200 ms to fully rupture the molecular junction. A constant voltage can be applied during the initial and final segments, as well as during the first and last 25 ms when the tip position is held fixed. During the central 100 ms while the tip is held, a voltage ramp can be applied. Current can be measured during the entire 500 ms procedure, as depicted in FIG. 10, 1001. IV data can be analyzed by first selecting traces with a molecular junction that sustains the entirety of the voltage ramp. Traces can be selected by using an automated algorithm that requires the conductance during the first and last 25 ms of the hold to be within the width of the molecular conductance histogram. IVs in TCB can be collected over a range of +/−1.05V, while IVs in PC can be collected over molecule dependent voltage ranges. After trace selection, all IVs for a given molecule can be used to construct a two dimensional current versus voltage histogram. A most probable IV can be obtained by fitting each vertical line slice of the two-dimensional IV histogram with a Gaussian and recording the peak current. This can then be converted to its linearly scaled IV curve.

By using electrodes with different areas coupled with an electrolytic environment, single-molecule diodes can be created with unprecedented rectification ratios at low operating voltages. Moreover, using symmetric molecules provides a simple method to create single-molecule junctions by self-assembly, without the tedious chemical modifications that have been commonly employed to control molecule directionality in a junction. Given the observed mechanism of rectification, this method can be implemented in other junctions beyond the STM-BJ test bed, using any electrode material including carbon nanotubes or graphene, by controlling the relative areas of electrodes exposed to solvents. By exploiting this tunable asymmetry in the electrostatic environment, this new approach offers a wealth of possibilities for translation into device fabrication.

The presently disclosed subject matter is not to be limited in scope by the specific embodiments herein. Indeed, various modifications of the disclosed subject matter in addition to those described herein will become apparent to those skilled in the art from the foregoing description and the accompanying figures. Such modifications are intended to fall within the scope of the appended claims.

1. A single-molecule diode using a polar environment, comprising:
a single-molecule adapted to be surrounded by the polar environment;
a first electrode, attached to a first end of the single-molecule, the first electrode having a first area adapted for exposure to the polar environment;
a second electrode, attached to a second end of the single-molecule, the second end being opposite the first end, the second electrode having a second area adapted for exposure to the polar environment;
wherein the first and second electrodes and the single-molecule form a single-molecule junction, and wherein the first area of the first electrode is larger than the second area of the second electrode, thereby creating an environmental asymmetry; and
a voltage source coupled to the first and second electrodes configured to selectively control the environmental asymmetry and thereby induce current rectification.

2. The single-molecule diode of claim 1, wherein the single-molecule comprises a symmetric single-molecule.

3. The single-molecule diode of claim 1, wherein the single-molecule comprises one of TDO3, TDO4, TDO5 flanked by two gold-binding methyl-sulfide bearing thiophenes.

4. The single-molecule diode of claim 1, wherein the single-molecule comprises one of 4,4′-bipyridine or 4,441 -diamino-p-terphenyl.

5. The single-molecule diode of claim 1, wherein the polar environment comprises a polar solution.

6. The single-molecule diode of claim 1, wherein the polar environment comprises propylene carbonate.

7. The single-molecule diode of claim 1, wherein the polar environment comprises one of water, an electrolytic solution, or an ionic liquid.

8. The single-molecule diode of claim 1, wherein the first and second electrodes are formed from the same material.

9. The single-molecule diode of claim 1, wherein the first and second electrodes are metal electrodes.

10. The single-molecule diode of claim 1, wherein the first and second electrodes are formed from gold.

11. The single-molecule diode of claim 1, wherein the first area of the first electrode is 1 mm² and the second area of the second electrode is 1 μm².

12. The single-molecule diode of claim 1, wherein the second electrode comprises an atomically sharp scanning tunneling microscope tip, the tip being insulated by a wax to expose a smaller second area of the second electrode.

13. A method for inducing rectification in a single-molecule junction, comprising:
surrounding a single-molecule by a polar environment;
attaching a first electrode attached to a first end of a single-molecule;
attaching a second electrode attached to a second end of the single-molecule, the second end being opposite the first end;
creating an environmental asymmetry by:
exposing a first area of the first electrode to a polar environment;
exposing a second area of the second area of the polar environment,
wherein the first area of the first electrode is larger than the second area of the second electrode; and
inducing rectification by selectively controlling the environmental asymmetry.

14. The method of claim 13, wherein the single-molecule comprises a symmetric single-molecule.

15. The method of claim 13, wherein the single-molecule comprises one of TDO3, TDO4, TDO5 flanked by two gold-binding methyl-sulfide bearing thiophenes.

16. The method of claim 13. wherein the single-molecule comprises one of 4,4′-bipyridine or 4,4″-diamino-p-terphenyl.

17. The method of claim 13, wherein the polar environment comprises a polar soluation.

18. The method of claim 13, wherein the polar environment comprises propylene carbonate.

19. The method of claim 13, wherein the polar environment comprises one of water, an electrolytic solution, or an ionic liquid.

20. The method of claim 13, wherein the first and second electrodes are formed from the same material.

21. The method of claim 13, wherein the first and second electrodes are metal electrodes.

22. The method of claim 13, wherein the first and second electrodes are formed from gold.

23. The method of claim 13, wherein the first area of the first electrode is 1 mm² and the second area of the second electrode is 1 μm².

24. The method of claim 13, wherein the second electrode comprises tip having the shape of a scanning tunneling microscope tip, the tip being insulated by a wax to expose only the second area of the second electrode.
